(19) United States
(12) Patent Application Publication
(10) Pub. No.: US 2024/0413726 A1
(43) Pub. Date: Dec. 12, 2024

(54) METHODS AND SYSTEMS FOR IMPROVING TRANSDUCER DYNAMICS

(71) Applicant: Cirrus Logic International Semiconductor Ltd., Edinburgh (GB)

(72) Inventors: Eric LINDEMANN, Boulder, CO (US); John L. MELANSON, Austin, TX (US); Emmanuel MARCHAIS, Dripping Springs, TX (US); Carl Lennart STÅHL, Malmö (SE)

(73) Assignee: Cirrus Logic International Semiconductor Ltd., Edinburgh (GB)

(21) Appl. No.: 18/807,608

(22) Filed: Aug. 16, 2024

Related U.S. Application Data
(63) Continuation of application No. 16/816,833, filed on Mar. 12, 2020.
(60) Provisional application No. 62/826,348, filed on Mar. 29, 2019.
(60) Provisional application No. 62/826,388, filed on Mar. 29, 2019.

(51) Int. Cl. H02K 33/00; B06B 1/02; B06B 1/04; G06F 1/02; G06F 3/01; G08B 6/00; H03F 1/02

(52) U.S. Cl. CPC H02K 33/00; B06B 1/0215; B06B 1/0261; B06B 1/045; G06F 1/022; G06F 3/016; G08B 6/00; H03F 1/0211

(57) ABSTRACT

A non-transitory computer readable medium may have stored thereon data encoding a waveform signal for playback, wherein the waveform signal is generated by implementing a discrete time model of a physical electromagnetic load that emulates a virtual electromagnetic load and modifying a raw waveform signal to generate a waveform signal for driving the physical electromagnetic load by modifying the virtual electromagnetic load to have a desired characteristic and applying the discrete time model to the raw waveform signal to generate the waveform signal for driving the physical electromagnetic load.

### RELATED APPLICATION

The present disclosure claims priority to U.S. patent application Ser. No. 16/816,833 filed Mar. 12, 2020, which in turn claims priority to both of U.S. Provisional Patent Application Ser. No. 62/826,348, filed Mar. 29, 2019, and U.S. Provisional Patent Application Ser. No. 62/826,388, filed Mar. 29, 2019, each of which is incorporated by reference herein in its entirety.

### FIELD OF DISCLOSURE

The present disclosure relates in general to improving dynamics of a transducer, for example, a haptic transducer.

### BACKGROUND

Vibro-haptic transducers, for example linear resonant actuators (LRAs), are widely used in portable devices such as mobile phones to generate vibrational feedback to a user. Vibro-haptic feedback in various forms creates different feelings of touch to a user's skin, and may play increasing roles in human-machine interactions for modern devices.

An LRA may be modelled as a mass-spring electro-mechanical vibration system. When driven with appropriately designed or controlled driving signals, an LRA may generate certain desired forms of vibrations. For example, a sharp and clear-cut vibration pattern on a user's finger may be used to create a sensation that mimics a mechanical button click. This clear-cut vibration may then be used as a virtual switch to replace mechanical buttons.

FIG. 1 illustrates an example of a vibro-haptic system in a device 100. Device 100 may comprise a controller 101 configured to control a signal applied to an amplifier 102. Amplifier 102 may then drive a haptic transducer 103 based on the signal. Controller 101 may be triggered by a trigger to output the signal. The trigger may for example comprise a pressure or force sensor on a screen or virtual button of device 100.

Among the various forms of vibro-haptic feedback, tonal vibrations of sustained duration may play an important role to notify the user of the device of certain predefined events, such as incoming calls or messages, emergency alerts, and timer warnings, etc. In order to generate tonal vibration notifications efficiently, it may be desirable to operate the haptic actuator at its resonance frequency.

The resonance frequency ƒ₀ of a haptic transducer may be approximately estimated as:

$${f}_{0} = \frac{1}{2 π \sqrt{CM}} \qquad ( 1 )$$

where C is the compliance of the spring system, and M is the equivalent moving mass, which may be determined based on both the actual moving part in the haptic transducer and the mass of the portable device holding the haptic transducer.

Due to sample-to-sample variations in individual haptic transducers, mobile device assembly variations, temporal component changes caused by aging, and use conditions such as various different strengths of a user gripping of the device, the vibration resonance of the haptic transducer may vary from time to time.

FIG. 2A illustrates an example of a linear resonant actuator (LRA) modelled as a linear system. LRAs are non-linear components that may behave differently depending on, for example, the voltage levels applied, the operating temperature, and the frequency of operation. However, these components may be modelled as linear components within certain conditions.

FIG. 2B illustrates an example of an LRA modelled as a linear system, including an electrically equivalent model of mass-spring system 201 of LRA. In this example, the LRA is modelled as a third order system having electrical and mechanical elements. In particular, Re and Le are the DC resistance and coil inductance of the coil-magnet system, respectively; and Bl is the magnetic force factor of the coil. The driving amplifier outputs the voltage waveform V(t) with the output impedance Ro. The terminal voltage V_{T} (t) may be sensed across the terminals of the haptic transducer. The mass-spring system 201 moves with velocity u(t).

In a system having an electromagnetic load such as an LRA, it may be desirable to determine the parameters that define an impedance of the electromagnetic load. Knowledge of such parameters may allow for optimization of playback of signals (e.g., playback of haptic waveforms) to the electromagnetic load. In addition, determination of electromagnetic load impedance may be valuable as it may allow for adapting of a playback signal to allow the playback signal to track changing parameters of the electromagnetic load.

An electromagnetic load such as an LRA may be characterized by its impedance Z_{Lra} as seen as the sum of a coil impedance Z_{coil} and a mechanical impedance Z_{mech}:

$${Z}_{Lra} = {Z}_{coil} + {Z}_{mech} \qquad ( 2 )$$

Coil impedance Z_{coil} may in turn comprise a direct current (DC) resistance Re in series with an inductance Le:

$${Z}_{c o i l} = R e + s * L e \qquad ( 3 )$$

Mechanical impedance Z_{mech} may be defined by three parameters including the resistance at resonance R_{RES} representing an electrical resistance representative of mechanical friction of the mass-spring system of the haptic transducer, a capacitance C_{MES} representing an electrical capacitance representative of an equivalent moving mass M of the mass-spring system of the haptic transducer, and inductance L_{CES} representative of a compliance C of the mass-spring system of the haptic transducer. The electrical equivalent of the total mechanical impedance is the parallel connection of R_{RES}, C_{MES}, L_{CES}. The Laplace transform of this parallel connection is described by:

$${Z}_{m e c h} ( s ) = \frac{1}{( \frac{1}{{R}_{R E S}} + \frac{1}{{L}_{{CES}^{* S}}} + {C}_{{MES}^{* S}} )} \qquad ( 4 )$$

The resonant frequency ƒ₀ of the haptic transducer can be represented as:

$${f}_{0} = \frac{1}{( 2 * π * \sqrt{{L}_{{CES}^{*}} {C}_{M E {S}^{*}}} )} \qquad ( 5 )$$

The quality factor Q of the LRA can be represented as:

$$Q = \frac{{R}_{RES} * R e}{{R}_{RES} + R e} * \sqrt{\frac{{C}_{MES}}{{L}_{CES}}} \qquad ( 6 )$$

Various physical parameters of an LRA, including resistance at resonance R_{ES}, angular resonant frequency ω₀ (e.g., ω₀=2πƒ₀), and quality factor q, may vary with temperature and process variations. It may be desirable to obtain a real-time estimate or system identification that tracks these changing parameters in order to model behavior of an LRA in order to maximize its performance. It may be particularly useful to obtain parameter estimates quickly, in a normal course of operation, without the need to introduce special calibration tones or procedures. Thus, it may further be useful to estimate transducer parameters (e.g., perform system identification) efficiently and quickly without disrupting normal operation of a transducer.

Referring to equation (6), it may appear non-intuitive that the expression involves a subexpression describing the parallel connection of resistances Re and

$${R}_{R E S} ( i . e . , \frac{{R}_{{RES}^{*}} R e}{{R}_{R E S} + R e} )$$

while in FIG. 2B these resistances are shown in a series connection. However, such may be the case where a driving voltage Ve is oscillating but then abruptly turns off and goes to zero. The voltage amplifier shown in FIG. 2B may be considered to have a low source impedance, ideally zero source impedance. Under these conditions, when driving voltage Ve goes to zero, the voltage amplifier effectively disappears from the circuit. At that point, the top-most terminal of resistance Re in FIG. 2B is grounded as is the bottom-most terminal of resistance R_{RES}, and so resistances Re and R_{RES} are indeed connected in parallel as reflected in equation (6).

### SUMMARY

In accordance with the teachings of the present disclosure, the disadvantages and problems associated with undesirable dynamics of an electromagnetic load may be reduced or eliminated.

In accordance with embodiments of the present disclosure, a non-transitory computer readable medium may have stored thereon data encoding a waveform signal for playback, wherein the waveform signal is generated by implementing a discrete time model of a physical electromagnetic load that emulates a virtual electromagnetic load and modifying a raw waveform signal to generate a waveform signal for driving the physical electromagnetic load by modifying the virtual electromagnetic load to have a desired characteristic and applying the discrete time model to the raw waveform signal to generate the waveform signal for driving the physical electromagnetic load.

In accordance with embodiments of the present disclosure, a method may include implementing a discrete time model of an electromagnetic load that emulates a virtual electromagnetic load and modifying a raw waveform signal to generate a waveform signal for driving the electromagnetic load by modifying the virtual electromagnetic load to have a desired characteristic, applying the discrete time model to the raw waveform signal to generate the waveform signal for driving the electromagnetic load, and storing the waveform signal to a non-transitory computer-readable medium.

In accordance with embodiments of the present disclosure, a system may include a signal generator configured to generate a raw waveform signal and a modeling subsystem configured to implement a discrete time model of an electromagnetic load that emulates a virtual electromagnetic load and further configured to modify the raw waveform signal to generate a waveform signal for driving the electromagnetic load by modifying the virtual electromagnetic load to have a desired characteristic, applying the discrete time model to the raw waveform signal to generate the waveform signal for driving the electromagnetic load, and storing the waveform signal to a non-transitory computer-readable medium.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates an example of a vibro-haptic system in a device, as is known in the art;

FIGS. 2A and 2B each illustrate an example of a Linear Resonant Actuator (LRA) modelled as a linear system, as is known in the art;

FIGS. 3A-3D each illustrate an example system for identifying mechanical impedance

FIG. 4 illustrates a graph of example waveforms of an electromagnetic load, as is known in the art;

FIG. 5 illustrates a graph of desirable example waveforms of an electromagnetic load, in accordance with embodiments of the present disclosure;

FIG. 6 illustrates an example system for improving transducer dynamics, in accordance with embodiments of the present disclosure; and

FIG. 7 illustrates an example of a Linear Resonant Actuator (LRA) modelled as a linear system and including a negative resistance, in accordance with embodiments of the present disclosure.

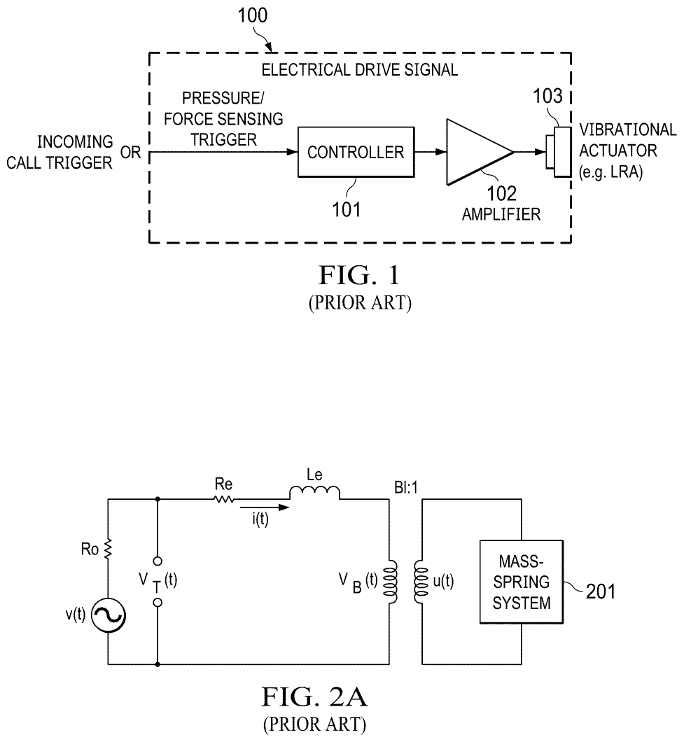

### DETAILED DESCRIPTION

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiment discussed below, and all such equivalents should be deemed as being encompassed by the present disclosure.

Various electronic devices or smart devices may have transducers, speakers, and acoustic output transducers, for example any transducer for converting a suitable electrical driving signal into an acoustic output such as a sonic pressure wave or mechanical vibration. For example, many electronic devices may include one or more speakers or loudspeakers for sound generation, for example, for playback of audio content, voice communications and/or for providing audible notifications.

Such speakers or loudspeakers may comprise an electromagnetic actuator, for example a voice coil motor, which is mechanically coupled to a flexible diaphragm, for example a conventional loudspeaker cone, or which is mechanically coupled to a surface of a device, for example the glass screen of a mobile device. Some electronic devices may also include acoustic output transducers capable of generating ultrasonic waves, for example for use in proximity detection type applications and/or machine-to-machine communication.

Many electronic devices may additionally or alternatively include more specialized acoustic output transducers, for example, haptic transducers, tailored for generating vibrations for haptic control feedback or notifications to a user. Additionally or alternatively, an electronic device may have a connector, e.g., a socket, for making a removable mating connection with a corresponding connector of an accessory apparatus and may be arranged to provide a driving signal to the connector so as to drive a transducer, of one or more of the types mentioned above, of the accessory apparatus when connected. Such an electronic device will thus comprise driving circuitry for driving the transducer of the host device or connected accessory with a suitable driving signal. For acoustic or haptic transducers, the driving signal will generally be an analog time varying voltage signal, for example, a time varying waveform.

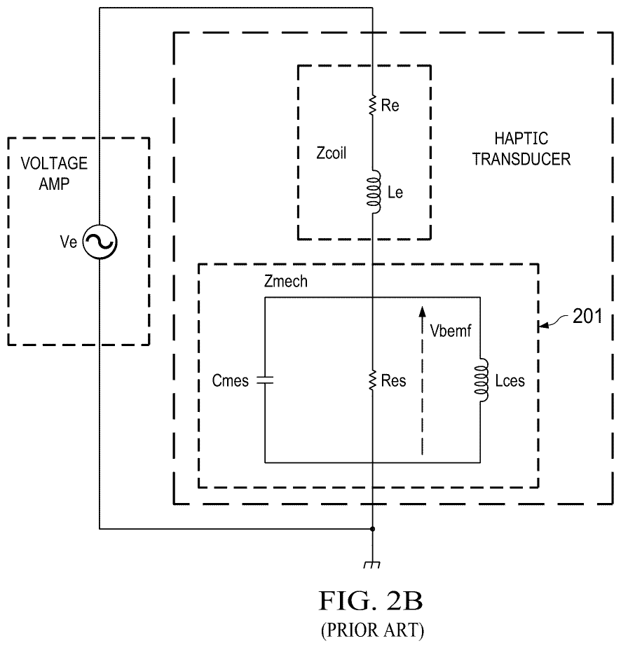

As previously mentioned, identifying parameters of an electromagnetic load may be useful for some types of haptic application. In the present disclosure, and as described in greater detail below, the transducer circuit model described in FIGS. 2A and 2B above may be modelled within a control system for the transducer. The transducer circuit model described above with respect to FIGS. 2A and 2B may correspond to a third-order rational function that describes the frequency response of the transducer. The coefficients of the rational function may be converted directly to estimates of the physical parameters—Re, Le, R_{ES}, C_{MES}, and L_{CES}—or to related parameters R_{ES}, ω₀, and q. In accordance with embodiments of the present disclosure, the coefficients of the rational function may also be used directly in a discrete-time infinite impulse response (IIR) filter that simulates the behavior of the transducer. This behavioral simulation may be useful, for example, in implementing a negative impedance digital filter that may be used to improve transducer dynamics as described herein and in U.S. Provisional Patent Application Ser. No. 62/826,348, filed Mar. 29, 2019 and in any application claiming priority thereto, all of which are incorporated by reference in their entireties.

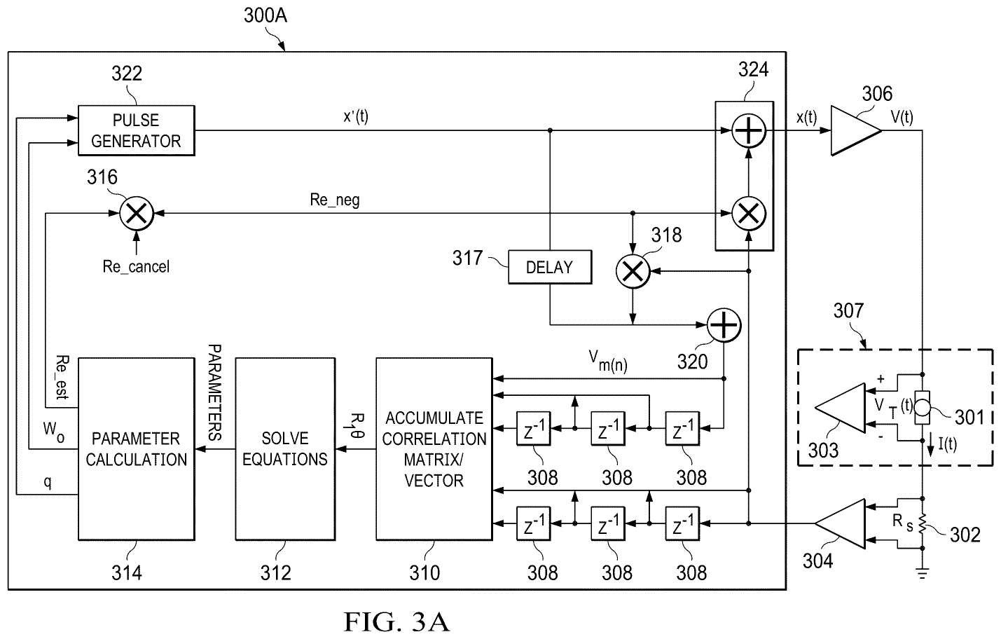

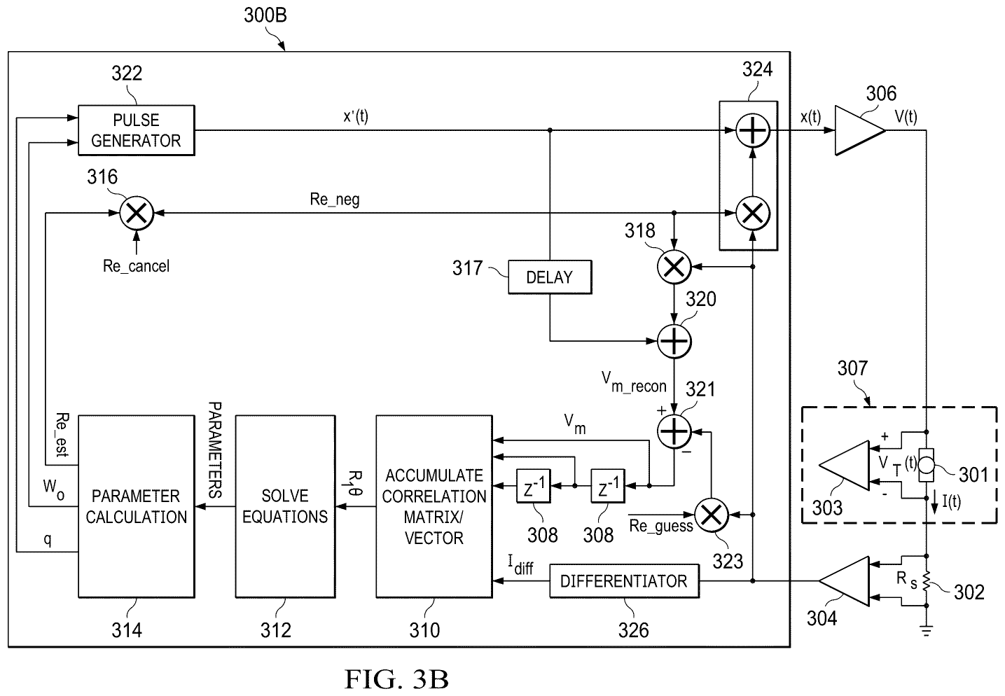

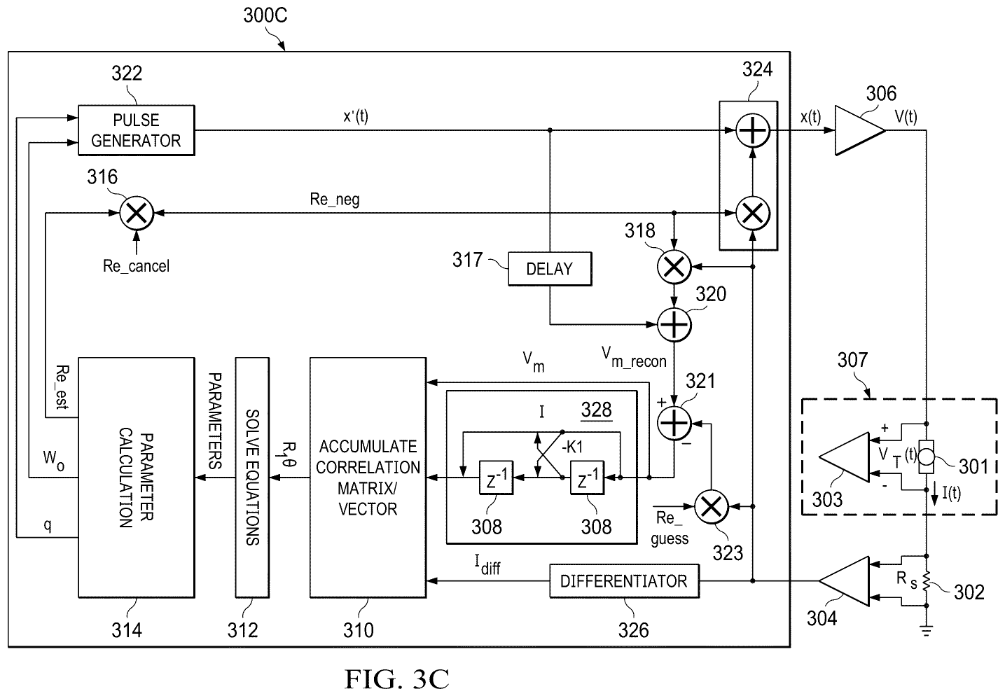

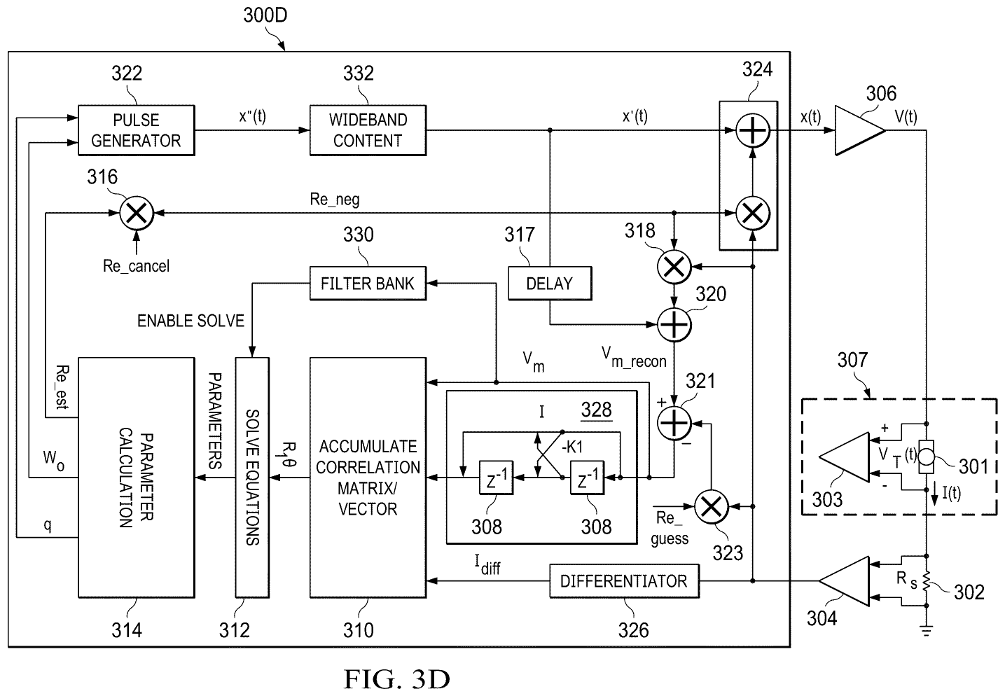

FIG. 3A illustrates an example system 300A for identifying parameters of an electromagnetic load, in accordance with embodiments of the present disclosure. In some embodiments, system 300A may be integral to a host device comprising system 300A and haptic transducer 301. Such device may include, without limitation, a mobile device, home application, a vehicle, and/or any other system, device, or apparatus that includes a human-machine interface.

In operation, a signal generator 324 of system 300A may generate a waveform signal x(t). Waveform signal x(t) may in turn be amplified by amplifier 306 to generate the driving signal V(t) for driving haptic transducer 301. Although FIG. 3A depicts haptic transducer 301, in some embodiments, another electromagnetic load (e.g., a loudspeaker, a microspeaker, a piezoelectric transducer) may be present in lieu of haptic transducer 301.

Responsive to driving signal V(t), a sensed terminal voltage V_{T}(t) of haptic transducer 301 may be converted to a digital representation by a first analog-to-digital converter (ADC) 303. Similarly, sensed current I(t) may be converted to a digital representation by a second ADC 304. Current I(t) may be sensed across a shunt resistor 302 having resistance Rₛ coupled to a terminal of haptic transducer 301. The terminal voltage V_{T} (t) may be sensed by a terminal voltage sensing block 307, for example a voltmeter.

These real-time digital estimates of sensed terminal voltage V_{T}(t) and sensed current I(t) may be made available to system 300A, which may be implemented in whole or in part by a central processing unit, digital signal processor, or other digital circuit. As shown in FIG. 3A and described in greater detail below, system 300A may employ least squares and related system identification techniques (e.g., least means square, recursive least squares, etc.) and use time-varying sensed voltage and current signals to compute an estimate of the rational function coefficients (e.g., transducer parameters) corresponding to a frequency response of haptic transducer 301. In system 300A as shown in FIG. 3A, some processing operations such as decimation, interpolation, and filtering of signals may not be shown in order for ease of exposition.

As shown in FIG. 3A, system 300A may use least squares linear regression to estimate transducer parameters. To perform linear regression, in principle, an accumulate correlation matrix/vector block 310 may form a regression matrix X from observed data, for example:

$$X = [ I ( n - 1 ) I ( n - 2 ) I ( n - 3 ) {V}_{m} ( n ) {V}_{m} ( n - 1 ) {V}_{m} ( n - 2 ) {V}_{m} ( n - 3 ) ]$$

wherein each term of the matrix may comprise an N-length column vector comprising samples having zero, one, two, or three delays. I(i) may represent a digital sample of sensed current I(t) and Vₘ(i) may represent a digital sample of an estimate of sensed terminal voltage V_{T}(t) that may be determined by combining (e.g., at combiner 320) a delayed (by delay block 317) version of a raw waveform signal x′(t) generated by pulse generator 322 with a product (e.g., calculated by multiplier 318) of a calculated negative resistance R_{e_neg} and sensed current I(t). Delayed values within regression matrix X may be determined by delaying digital samples with appropriate delay blocks 308. Thus, regression matrix X may comprise an N×7 matrix where N is the number of samples (e.g., N=813=17 milliseconds of samples at 48 kHz).

Accumulate correlation matrix/vector block 310 may also form an N×1 vector y from output data of the linear regression, in this case the undelayed digitally-sampled sensed current I(n), for example:

y=[I(n)]

If a parameter vector is defined as:

params=[α1α2α3b0b1b2b3]^{T}
then the third order difference equation above may be rewritten in matrix/vector form as:

$$y = X * params$$

which suggests that parameters params may be found by solving:

$$params = {X}^{- 1} * y$$

Because X may be an N×7 rectangular matrix and y has dimensions N×1, and because N is likely to be much greater than 7, the relationships described above may correspond to a highly overdetermined system of equations. Thus, such system of equations may be solved in a least-squares sense—that is, for parameters params—that minimizes the sum of (y−X*params_estimate)². To accomplish this determination, both sides of the original regression equation may be multiplied by X^{T}:

$${X}^{T} * y = {X}^{T} * X * params$$

If θ is defined as θ=X^{T}*y and R is defined as R=X^{T}*X, then θ=R*params and params=R⁻¹*y.

R may thus be a square 7*7 matrix whose entries are the sample auto-correlation and cross-correlations of the columns of the regression matrix X, and θ may be a 7×1 vector of sample cross-correlations of the output undelayed I(n) column vector with the 7 columns of X. This set of equations may be “normal equations” often encountered in statistical signal processing. When correlation or cross-correlation matrices is referenced in this disclosure, it is to be understood that covariance or cross-covariation matrices is referring to substantially the same type of matrices.

The normal equations in this case may represent a system of seven equations in seven unknowns and may be solved for parameters params using a variety of linear algebra techniques including, but not limited to, Gaussian Elimination, Gauss-Jordan, Matrix Inversion, Cholesky Decomposition, and others. In the present disclosure, the simplest of these techniques, Gaussian Elimination, may be emphasized.

The form of the normal equations enables a useful structure for the system identification and model estimation: for every sample (e.g., at 48 kHz or even a lower decimated sample rate), accumulate correlation matrix/vector block 310 may update R and θ correlations from I(i) and Vₘ(i) (e.g., only R and θ may be maintained in memory and are updated in every sample). Such updates may simply be multiply-accumulate operations. The matrix X or vector y may never be stored or computed in memory—just the correlations R and θ.

When parameters params are desired to be updated, solve equations block 312 may solve R⁻¹*y, for example by using Gaussian Elimination. A Gaussian Elimination operation may occur over a typical digital signal processor signal processing frame—(e.g., 48 samples at 48 kHz)—or even be spread over a number of frames.

It may be likely that solve equations block 312 may solve the simultaneous equations once or twice per haptic pulse. For example, for a long haptic pulse generated by a raw waveform signal x′(t) having, for example, ten sinusoidal cycles, digitized samples of the sensed terminal voltage V_{T}(t) and sensed current I(t) of just the first three cycles may be selected, and a least-squares system identification may need to be determined based only on these three cycle regions. Then, in the case where the estimated model parameters are used to control a negative impedance system, such as described in the previously referenced U.S. Provisional Patent Application Ser. No. 62/826,348, the parameters of a negative impedance IIR filter may be updated shortly after the first three cycles, for example by the fourth cycle, so that when raw waveform signal x′(t) ends after ten cycles, the new estimated model parameters may be in place and may be able to ensure good braking of the haptic pulse, and thus prevent the pulse from ringing far beyond the tenth cycle.

Similarly, another three cycle region of digitized samples of the sensed terminal voltage V_{T}(t) and sensed current I(t) after raw waveform signal x′(t) ends may be selected and system 300A may perform an additional least-squares estimate based on these cycles to further update the model parameters to assure good braking of the haptic pulse. Alternatively, for a short haptic pulse (e.g., raw waveform signal x′(t) for just two cycles), a region of three cycles of digitized samples of the sensed terminal voltage V_{T}(t) and sensed current I(t) corresponding to the start of the pulse and including one cycle after the end of the pulse may be selected to perform the system identification.

As just described, raw waveform signal x′(t) often comprises of a small number of cycles of a sinusoid or other narrow-band stimulus. Narrow-band stimuli are often discouraged in system identification applications, because they only excite a limited frequency range of the system. However, by selecting transient regions near the start and stop of a pulse, the wideband transient effects that occur when the sinusoid or narrow band input abruptly turns on or off may be included. Thus, the wideband spectrum associated with the start and/or stop of the selected transient region may provide the necessary wideband stimulus to permit accurate system identification.

System identification of various systems is often performed using least mean squares (LMS), recursive least squares (RLS), or other recursive techniques. These techniques are, in fact, often derived from the description of least-squares and normal equations provided above. However, these techniques often have an explicit or implicit “forgetting factor” that emphasizes the most recent samples of the selected regions at the expense of samples earlier in the region. This emphasizing of most recent samples may be counterproductive in the case where the abrupt start or stop of the input is being relied upon to provide the wideband transient stimulus required for accurate system identification. For this reason, direct computation of the correlation matrix R and cross-correlation matrix θ and corresponding solution of the simultaneous normal equations may be emphasized. The first few samples of a selected transient region may be weighted at least as highly as the last samples of a selected transient region. This approach may enable performance of rapid and accurate least-squares system identification during normal system operation, rather than having to resort to special calibration modes that require broadband noise stimuli or pilot tones.

The sample-by-sample accumulation of matrices R and θ associated with least-squares estimation, previously described above, may enable system 300A to avoid storing sampled segments of sensed terminal voltage V_{T}(t) and sensed current I(t). Only the correlation matrices may be stored and updated every sample. When a new set of model parameters is desired, the normal equations may be solved or may result in simplified subsets to be described below. The solution of these equations may be spread out across a number of samples—for example one or more sample frames (e.g., where each frame is 48 samples)—to provide efficient distribution of real-time computation. As mentioned, it may be desirable for system 300A to solve the equations once or twice per haptic pulse.

Examples herein may use sensed terminal voltage V_{T}(t) and sensed current I(t) corresponding to the first 17 milliseconds (e.g., three input cycles at ˜176 Hz) of a haptic pulse. Of these 17 milliseconds, the first few milliseconds may be very important as they include wideband information associated with the onset transient of the haptic stimulus. As mentioned above, such haptic pulse characteristics are one of the reasons the use of LMS or RLS with a “forgetting factor” is not desired. Such techniques would deemphasize the first few milliseconds of the 17 milliseconds of samples of sensed terminal voltage V_{T}(t) and sensed current I(t) in favor of the last few milliseconds. If anything, such techniques result in the opposite of what is desired.

However, it may also not be desired for the sample-by-sample accumulation of correlations of matrices R and θ to go on uninterrupted forever. Instead, accumulate correlation matrix/vector block 310 may explicitly reset matrices R and θ to zero at appropriate times (e.g., at the beginning of a haptic pulse). Accumulate correlation matrix/vector block 310 may accumulate correlations of R and θ until the simultaneous equations are solved (e.g., after 17 milliseconds). If it is desired to perform a further solution of the simultaneous equations later in the pulse that also includes the start transient data, then accumulate correlation matrix/vector block 310 may continue the accumulation of correlations until the next time the equations are solved. For example, in some embodiments, system 300A may solve the simultaneous equations a second time 1-2 milliseconds after raw waveform signal x′(t) ends. At that point, matrices R and θ may reflect both the wideband transient behavior of the start of raw waveform signal x′(t) and the wideband transient behavior due to an abrupt stop of raw waveform signal x′(t). This combined start and stop wideband transient behavior may provide a particularly rich set of correlations and may lead to a robust estimate of model parameters. System 300A may also save parameter estimates from one haptic pulse to the next pulse so that they may be used, for example as initial negative impedance IIR filter conditions, in future estimates.

The parameters determined by the least-squares system identification are coefficients of a rational function, or equivalently of a difference equation, that describes the electrical equivalent impedance of the physical LRA. For example the expression:

$${Z}_{L R A} = ( b 0 + b 1 * {z}^{- 1} + b 2 * {z}^{- 2} + b 3 * {z}^{- 3} ) / ( 1 - a 1 * {z}^{- 1} - a 2 * {z}^{- 2} - a 3 * {z}^{- 1} )$$

involves the seven parameters b0, b1, b2, b3, α1, α2, α3 which may be seven parameters params determined from least-squares estimation as described above. These seven parameters may also serve as the parameters of a digital IIR filter that provides a digital model of the LRA behavior and may be used to control a negative impedance system, such as described in the previously referenced U.S. Provisional Patent Application Ser. No. 62/826,348.

A parameter calculation block 314 may translate these coefficients to physical parameters—for example, DC resistance Re, angular resonant frequency ω₀ (or resonant frequency ƒ₀), and quality factor q—using algebraic calculations as described below. For example, parameter calculation block 314 may calculate an estimate R_{e_est} for DC resistance Re as the direct current value (e.g., z=1) of the impedance given in the above expression for Z_{LRA} by sensed terminal voltage V_{T} (t) divided by sensed current I(t). Substituting for z=1 in the above expression for Z_{LRA} provides an expression for the DC resistance:

$${R}_{{e}_{-} e s t} = ( b 0 + b 1 + b 2 + b 3 ) / ( 1 - a 1 - a 2 - a 3 )$$

To obtain estimates for quality factor q and resonant frequency ƒ₀ of transducer 301, parameter calculation block 314 may convert the complex conjugate discrete time z-domain poles and zeros of the estimated impedance transfer function given above to continuous time s-domain poles and zeros:

$$\begin{matrix}{p}_{c o n t} = log ( p ) * {f}_{s} ; \\ {𝓏}_{c o n t} = log ( 𝓏 ) * {f}_{s}\end{matrix}$$

where p and z are the discrete time complex poles and zeros of the impedance transfer function described by the rational function model parameters determined by least-squares system identification, p_{cont} and z_{cont} are s-domain continuous time poles and zeros, and ƒₛ is the sampling frequency in the discrete-time domain.

An estimated damping factor ζₑₛₜ and an estimated quality factor qₑₛₜ for entire transducer 301 (both mechanical and electrical components together) may be given by:

$$\begin{matrix}{ζ}_{e s t} = real ( {𝓏}_{c o n t} ) ; and \\ {q}_{e s t} = 1 / ( 2 * {ζ}_{e s t} ) .\end{matrix}$$

The estimated mechanical damping factor ζ_{mech_est} and estimate mechanical quality factor q_{mech_est} may be given by:

$$\begin{matrix}{ζ}_{mech\_est} = real ( {p}_{cont} ) ; and \\ {q}_{mech\_est} = 1 / ( 2 * {ζ}_{mech\_est} ) .\end{matrix}$$

Estimated resonant frequency ƒ_{0_est} of transducer 301 may be given by

$${f}_{0 \_ est} = \vert {p}_{c o n t} / 2 π \vert$$

It may be the case that an explicit expression for estimated coil inductance Le is not of interest, although the information for determining coil inductance Le may be within estimated rational function least-squares parameters params. For example, it may be the case that a negative impedance system uses only estimated DC resistance R_{e_est} in a negative impedance feedback path rather than estimated DC resistance R_{e_est} and estimated coil inductance Le in series, or that a feedback path consists of estimated DC resistance R_{e_est} in series with a fixed, predetermined value coil inductance Le.

Thus, from parameters params, parameter calculation block 314 may calculate physical parameters of transducer 301, including DC resistance Re, angular resonant frequency ω₀, and quality factor q. From angular resonant frequency ω₀ and quality factor q, pulse generator 322 may generate raw waveform signal x′(t), for example, having a frequency at or near angular resonant frequency ω₀ in order to provide the strongest haptic effect at transducer 301. Further, system 300A may apply (e.g., at multiplier 316) a multiplicative factor R_{e_cancel} to an estimated DC resistance Re R_{e_est}, to generate a negative resistance R_{e_neg} that may be applied by signal generator 324 to raw waveform signal x′(t) in order to generate waveform signal x(t).

Although system 300A may estimate from a short sinusoidal pulse, improved performance may also be possible with the addition of multiple sinusoids. For example, subharmonic or superharmonic sinusoids may be added at frequencies lower than or higher than the principle sinusoid. The addition of such other sinusoids may increase the bandwidth for the steady-state stimulus.

FIG. 3B illustrates an example system 300B for identifying parameters of an electromagnetic load, in accordance with embodiments of the present disclosure. In some embodiments, system 300B may be integral to a host device comprising system 300B and haptic transducer 301. Such device may include, without limitation, a mobile device, home application, a vehicle, and/or any other system, device, or apparatus that includes a human-machine interface. System 300B may be similar in many respects to system 300A, and thus, only certain differences between system 300B and system 300A may be discussed below.

The solution described above with respect to system 300A may involve inverting, or equivalently finding a more numerically robust “pseudo-inverse” of a 7×7 matrix. This solution may be numerically challenging, especially in fixed-point implementations. The size of the 7×7 matrix may be reduced by observing that there are certain fixed relationships between the numerator and denominator coefficients of the rational function. For example, estimated DC resistance R_{e_est} may be determined separately by averaging:

$${R}_{e \_ est} = \sqrt{\overline{( \frac{{{V}_{T \_ LP} ( t )}^{2}}{{{I}_{L P} ( t )}^{2}} )}}$$

wherein the bar under the radical represents an average of the fraction under the radical, V_{T}_{_{LP}}(t) is a low-pass filtered version of V_{T}(t) and I_{LP}(t) is a low-pass filtered version of I(t), wherein the low-pass cutoff frequency of a filter for generating such low-pass filtered versions is lower than resonant frequency ƒ₀ of transducer 301.

If coil inductance Le is known a-priori, within acceptable tolerance (e.g., by laboratory measurements), or is otherwise estimated, then a discrete time model of the coil impedance Z_{coil} may be given as:

$${Z}_{c o i l} = \frac{( R e + 2 L e {f}_{s} ) z + R e - 2 L e {f}_{s}}{z + 1}$$

Coil impedance Z_{coil} may be eliminated from the estimation problem by forming the signal:

$${V}_{m} ( z ) = {V}_{T} ( z ) - {Z}_{c o i l} I ( z )$$

wherein Z_{coil}(z) may simply be sensed current I(z) filtered by a difference equation corresponding to the rational expression for coil impedance Z_{coil}.

Instead of estimating the full LRA impedance

$${Z}_{L r a} ( z ) = \frac{{V}_{T} ( z )}{I ( z )} ,$$

mechanical impedance Z_{mech} may be estimated as:

$${Z}_{m e c h} ( z ) = \frac{{V}_{m} ( z )}{I ( z )}$$

This equation for mechanical impedance Z_{mech} may be rewritten in the form:

$${Z}_{m e c h} ( z ) = \frac{{t}_{b 0} - {t}_{b 2} {z}^{- 2}}{{t}_{a 0} + {t}_{a 1} {z}^{- 1} + {t}_{a 2} {z}^{- 2}} = \frac{{t}_{g} ( 1 - {z}^{- 2} )}{{t}_{a 0} + {t}_{a 1} {z}^{- 1} + {t}_{a 2} {z}^{- 2}}$$

$$wherein : {t}_{g} = {t}_{b 0} = {t}_{b 2} = 2 {L}_{C E S} {R}_{R E S} {f}_{s}$$

$${t}_{a 0} = 4 {C}_{M E S} {L}_{C E S} {R}_{R E S} {f}_{s}^{2} + 2 {L}_{C E S} {f}_{s} + {R}_{R E S}$$

$${t}_{a 1} = - 8 {C}_{M E S} {L}_{C E S} {R}_{R E S} {f}_{s}^{2} + 2 {R}_{R E S}$$

$${t}_{a 2} = 4 {C}_{M E S} {L}_{C E S} {R}_{R E S} {f}_{s}^{2} - 2 {L}_{C E S} {f}_{s} + {R}_{R E S}$$

A differentiator 326 may further differentiate sensed current I(t), resulting in:

$${I}_{d i f f} ( z ) = I ( z ) ( 1 - {z}^{- 2} )$$

wherein (1−z⁻²) may correspond to a transfer function of differentiator 326 with impulse response [1 0 −1]. Instead of estimating full LRA impedance Z_{Lra} as above, the following expression for a differential mechanical impedance Z_{mech_diff_est} may be estimated as follows:

$${Z}_{mech \_ diff \_ est} ( z ) = \frac{{V}_{m \_ mech} ( z )}{{I}_{d i f f} ( z )}$$

which may be written as:

$${Z}_{mech \_ diff \_ est} ( z ) = \frac{{t}_{g}}{{t}_{a 0} + {t}_{a 1} {z}^{- 1} + {t}_{a 2} {z}^{- 2}}$$

or equivalently by dividing both the numerator and denominator by t_{g} as:

$${Z}_{mech \_ diff \_ est} ( z ) = \frac{1}{{t}_{a 0} / {t}_{g} + {t}_{a 1} {z}^{- 1} / {t}_{g} + {t}_{a 2} {z}^{- 2} / {t}_{g}}$$

Using the following definitions:

$${p}_{a 0} = {t}_{a 0} / {t}_{g} ;$$

$${p}_{a 1} = {t}_{a 1} / {t}_{g} ;$$

$$and {p}_{a 2} = {t}_{a 2} / {t}_{g}$$

then the expression for differential mechanical impedance Z_{mech_diff_est} may be rewritten as follows:

$${Z}_{mech \_ diff \_ est} ( z ) = \frac{1}{{p}_{a 0} + {p}_{a 1} {z}^{- 1} + {p}_{a 2} {z}^{- 2}}$$

which may correspond to the difference equation:

$${I}_{d i f f} ( n ) = {v}_{m} ( n ) + {v}_{m} ( n - 1 ) + {v}_{m} ( n - 2 )$$

Accumulate correlation matrix/vector block 310 may estimate (e.g., using least-squares regression) the parameters p_{α0}, p_{α1}, and p_{α2} with signals Vₘ and I_{diff} as input and output data. Such estimation may involve the inversion of a 3×3 matrix, which may be simpler than the 7×7 matrix described above with respect to system 300A.

By dividing the numerator and denominator of the previous expression for differential mechanical impedance Z_{mech_diff_est} by parameter p_{α0}, it may be put into a more standard digital signal processing form of:

$${Z}_{mech \_ diff \_ est} ( z ) = \frac{g}{1 + {a}_{1} {z}^{- 1} + {a}_{2} {z}^{- 2}}$$

$$where : g = \frac{1}{{p}_{a 0}} ;$$

$${a}_{1} = \frac{{p}_{a 1}}{{p}_{a 0}} ;$$

$$and {a}_{2} = \frac{{p}_{a 2}}{{p}_{a 0}}$$

System 300B depicts a system for performing the least-squares regression described above, with a somewhat simpler variant, in that sensed voltage signal V_{T}(t) corresponds in FIG. 3B to reconstructed voltage signal V_{m_recon} and voltage signal Vₘ=V_{T}(t)−Rel(t) (e.g., rather than Vₘ=V_{T}(t)−Z_{coil}I(t)). However, the inclusion of coil inductance Le in coil impedance Z_{coil} may result in a more accurate estimate of differential mechanical impedance Z_{mech_diff_est}(z) by accumulate correlation matrix/vector block 310.

Based on the estimated differential mechanical impedance Z_{mech_diff_est}(z) and resulting parameters g, α₁, and α₂, system 300B may compute and estimate full LRA impedance Z_{Lra} using a predetermined estimated DC resistance Re and coil inductance Le:

$${Z}_{lra \_ est} ( z ) = {Z}_{mech \_ diff \_ est} ( z ) ( 1 + {z}^{- 2} ) + {Z}_{c o i l}$$

The result may be a three-pole, three-zero rational function with the same form as that obtained by the 7×7 correlation matrix estimation of system 300A.

The inverse of estimated full LRA impedance Z_{lra_est} (z) may be given by:

$${G}_{Lra \_ est} ( z ) = \frac{I ( z )}{{V}_{T} ( z )} ≅ inverse ( {Z}_{lra \_ est} ( z ) )$$

which corresponds to a third-order difference equation. Sensed voltage V_{T}(t) may be filtered by this third-order difference equation to generate a predicted sensed current I_{pred}:

I_{pred}(z)=V_{T}(z)G_{Lra_est}(z)

Because a direct measure of sensed current I(t) is available in system 300B, a squared error may be computed as:

$${error}_{est} = {( {I}_{pred} ( t ) - I ( t ) )}^{2}$$

Another approach to estimating DC resistance Re may be to begin with a guess, shown in FIG. 3B as Re_guess, and then iterate the estimation full LRA impedance Z_{Lra_est}, computing error errorₑₛₜ based on resistance guess Re_guess. After each iteration, system 300B may adjust resistance guess Re_guess following a gradient descent on error errorₑₛₜ as a function of resistance guess Re_guess, until the change in resistance guess Re_guess falls below a pre-defined tolerance.

FIG. 3C illustrates an example system 300C for identifying parameters of an electromagnetic load, in accordance with embodiments of the present disclosure. In some embodiments, system 300C may be integral to a host device comprising system 300C and haptic transducer 301. Such device may include, without limitation, a mobile device, home application, a vehicle, and/or any other system, device, or apparatus that includes a human-machine interface. System 300C may be similar in many respects to system 300B, and thus, only certain differences between system 300C and system 300B may be discussed below.

It may be desirable for regressor signals that are used to form correlation matrices to be uncorrelated between themselves. Such decorrelation may diagonalize much of the correlation matrix, which may lead to numerically superior results. System 300C may include a lattice filter 328 to accomplish such decorrelation of signals, as shown in FIG. 3C. One interesting property of the specific lattice filter coefficients chosen in FIG. 3C is that the second tap output of lattice filter 328 may be a notch filter at the resonant frequency ƒ₀ of transducer 301. Such property may mean that a ratio of the smoothed magnitude of the second tap signal of lattice filter 328 may be used to estimate DC resistance Re with less low-pass filtering than that described above in the ratio of low-pass filtered sensed voltage signal V_{T}(t) and sensed current signal I(t) because the large changes in impedance at resonant frequency ƒ₀ may be largely eliminated by the notch output of the second tap of lattice filter 328. Accordingly, system 300C may use a simpler low-pass filter (e.g., than that of system 300B) to eliminate effects of coil inductance Le which may be significant at higher frequencies well above resonance.

FIG. 3D illustrates an example system 300D for identifying parameters of an electromagnetic load, in accordance with embodiments of the present disclosure. In some embodiments, system 300D may be integral to a host device comprising system 300D and haptic transducer 301. Such device may include, without limitation, a mobile device, home application, a vehicle, and/or any other system, device, or apparatus that includes a human-machine interface. System 300D may be similar in many respects to system 300D, and thus, only certain differences between system 300D and system 300C may be discussed below.

In some instances, it may be desired to form an explicit estimate of the broadband content of voltage signal Vₘ. If voltage signal Vₘ is determined to be sufficiently broadband, then solution of the normal equations may be enabled. Otherwise, the solution to the normal equation may be disabled.

As shown in FIG. 3D, system 300D may include filter bank 330. Filter bank 330 may receive voltage signal Vₘ as input and pass it through a bank of filter channels of different frequencies. If the output of filter bank 330 shows sufficient energy in a wide range of frequency bands, then voltage signal Vₘ may be a wideband signal. Filter bank 330 may generate an ENABLE SOLVE signal which may be input to solve equations block 312 to enable solution of the normal equations after voltage signal Vₘ has been explicitly determined to be sufficiently broadband. It will be recognized by those skilled in the art of spectral estimation, that there are many ways to measure the spectrum and bandwidth of a signal. Any of these methods, including parametric spectral estimation techniques and spectral tilt estimates may be used in place of filter bank 330 to form an estimate of the bandwidth of voltage signal Vₘ in order to generate the ENABLE SOLVE signal.

In order to guarantee a broadband Vₘ signal to facilitate parameter estimation, it may be desired to artificially add broadband content to the output of pulse generator 322. Accordingly, a wideband content block 332 of system 300D may receive a raw waveform signal x″(t) from pulse generator 322 and add wideband content to such signal to generate modified raw waveform signal x′(t) for input to signal generator 324. Wideband content block 332 may use any suitable approach to add wideband content to raw waveform signal x″(t) to generate modified raw waveform signal x′(t). For example, in some embodiments, wideband content block 332 may comprise a wideband noise generator whose output may be added or multiplied with raw waveform signal x″(t) to generate modified raw waveform signal x′(t). In other embodiments, wideband content block may comprise a distortion circuit configured to clip or otherwise distort raw waveform signal x″(t) to increase its wideband content. As a further example, wideband content block 332 may comprise a modulation circuit to modulate raw waveform signal x″(t) to increase its wideband content.

The foregoing discloses example embodiments of systems and methods for least-squares estimation for finding the parameters of a transducer, and several embodiments for constraining and simplifying the least-squares estimation have been illustrated and discussed. This constraining and simplifying may allow for quickly and efficiently estimating the parameters of a transducer in real-time without interfering with the normal operation of the system.

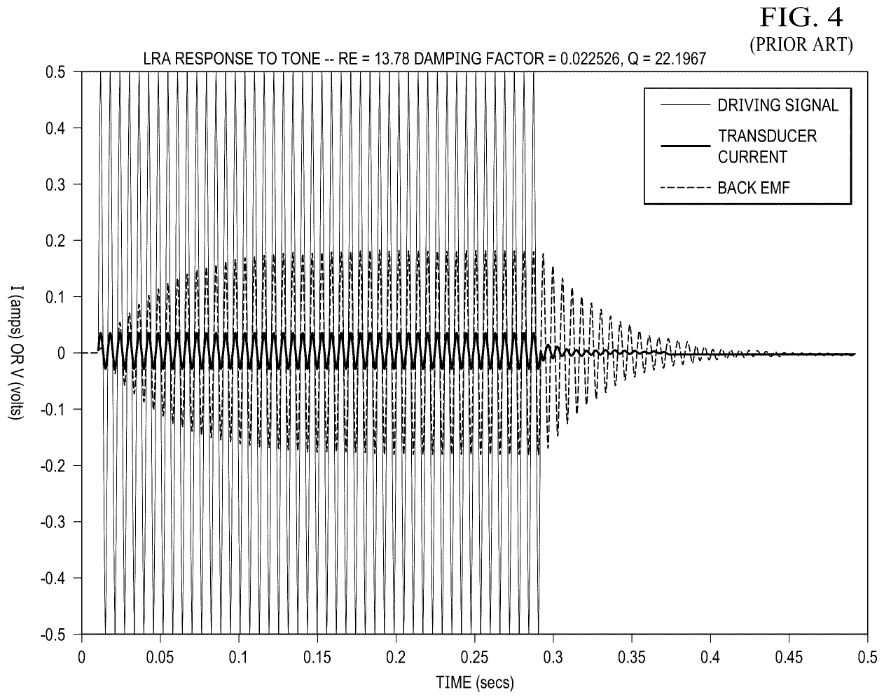

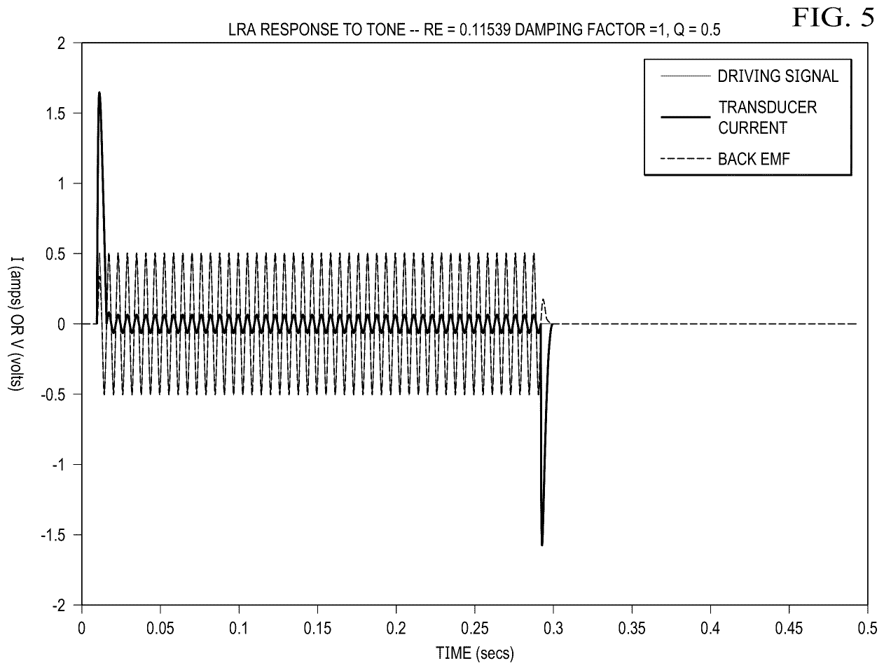

Electromagnetic transducers, such as LRAs or microspeakers, may have slow response times. FIG. 4 is a graph of an example response of an LRA, depicting an example driving signal to the LRA, a current through the LRA, and a back electromotive force (back EMF) of the LRA, wherein such back EMF may be proportional to the velocity of a moving element (e.g., coil or magnet) of the transducer. As shown in FIG. 4, the attack time of the back EMF may be slow as energy is transferred to the LRA, and some “ringing” of the back EMF may occur after the driving signal has ended as the mechanical energy stored in the LRA is discharged. In the context of a haptic LRA, such behavioral characteristic may result in a “mushy” feeling click or pulse, instead of a “crisp” tactile response. Thus, it may be desirable for an LRA to instead have a response similar to that shown in FIG. 5, in which there exists minimal ringing after the driving signal has ended, and which may provide a more “crisp” tactile response in a haptic context. Accordingly, it may be desirable to apply processing to a driving signal such that when the processed driving signal is applied to the transducer, the velocity or back EMF of the transducer more closely approaches that of FIG. 5. The problem illustrated in FIG. 4 may result from a transducer 301 with a high quality factor Q with a sharp peak in impedance at a resonant frequency ƒ₀ of the transducer.

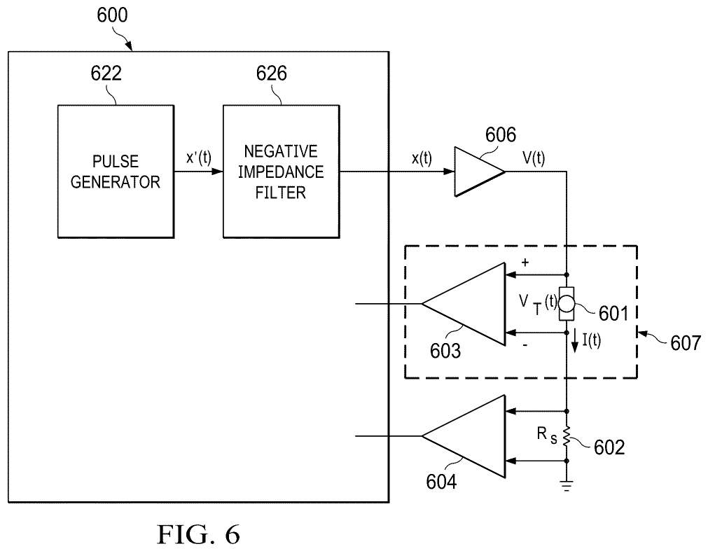

FIG. 6 illustrates example system 600 for improving dynamics of an electromagnetic load, in accordance with embodiments of the present disclosure. In some embodiments, system 600 may be integral to a host device comprising system 600 and haptic transducer 601. Such device may include, without limitation, a mobile device, home application, a vehicle, and/or any other system, device, or apparatus that includes a human-machine interface. As described in greater detail below, a system 600 may implement negative impedance filter 626 to apply to the raw transducer driving signal, which may reduce an effective quality factor Q of the transducer, which may in turn decrease attack time and minimize ringing occurring after the raw transducer driving signal has ended. Quality factor Q of a transducer may be expressed as:

$${Q}_{LRA} = \frac{{R}_{RES} * Re}{{R}_{RES} + Re} * \sqrt{\frac{{C}_{MES}}{{L}_{CES}}} \qquad ( 7 )$$

In equation (7), as DC resistance Re increases, the numerator term R_{RES}*Re increases more rapidly than the denominator term R_{RES}+Re. Therefore, quality factor Q_{LRA} generally increases with increasing DC resistance Re. Accordingly, one way system 600 may minimize quality factor q is to effectively decrease DC resistance Re. In some embodiments, system 600 may ideally decrease the effective DC resistance Re to a point in which critical damping occurs in transducer 601.

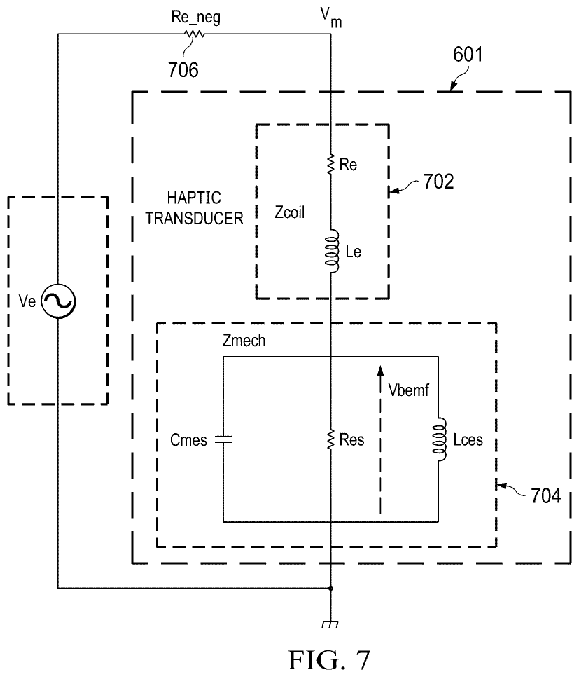

FIG. 7 illustrates an example of haptic transducer 601 modelled as a linear system including electrical components 702 and electrical model of mechanical components 704 and including a negative resistance resistor 706 with negative impedance Re_neg inserted in series with haptic transducer 601, in accordance with embodiments of the present disclosure. The addition of negative impedance Re_neg may lower quality factor Q_{LRA} because effectively it subtracts from DC resistance Re thereby reducing the overall DC electrical impedance.

In practice, negative resistors do not exist. Instead, negative impedance filter 626 may comprise a digital filter configured to behave substantially like the circuit shown in FIG. 7, including a mathematical model of negative impedance Re_neg in series with a mathematical model of haptic transducer 601. In operation, negative impedance filter 626 may in effect compute a voltage Vₘ that would occur at the junction of negative impedance Re_neg and DC resistance Re as shown in FIG. 7, if, in fact, it were possible to place a physical resistor with negative impedance Re_neg in series with haptic transducer 601. Computed voltage Vₘ may then be used to drive haptic transducer 601.

From an examination of FIG. 7, a Laplace transform relationship between voltage Vₘ and a driving voltage Vₑ may be given by

$${V}_{m} ( s ) = {V}_{e} ( s ) * \frac{{Z}_{LRA} ( s )}{( {Z}_{LRA} ( s ) - Re\_neg )} \qquad ( 8 )$$

Equation (8) is effectively a voltage divider that outputs Vₘ given input Vₑ. Negative impedance filter 626 may be a digital filter that implements a digital version of the transfer function:

$${Z}_{NIF} ( s ) = \frac{{Z}_{LRA} ( s )}{( {Z}_{LRA} ( s ) - Re\_neg )} \qquad ( 9 )$$

Raw waveform signal x′(t) generated by pulse generator 622 and driven to negative impedance filter 626 in system 600 may correspond to a digital representation of driving voltage Vₑ shown in FIG. 7. Waveform signal x(t) generated by negative impedance filter 626 may in turn correspond to voltage Vₘ. Voltage Vₘ may be input to amplifier 606, which in turn may drive haptic transducer 601.

In some embodiments, negative impedance Re_neg may be represented as a fraction of DC resistance Re:

$$Re\_neg = Re * Re\_cancel \qquad ( 10 )$$

Where factor Re_cancel may comprise a unitless value between 0 and 1, and may be chosen a-priori, representing the fraction of DC resistance Re that is to be cancelled by negative impedance filter 626.

Negative impedance filter 626 may implement a digital filter with transfer function corresponding to equation (9). Assuming that negative impedance Re_neg is given by equation (10), then implementation of negative impedance filter 626 as a digital filter may require a digital estimate of transducer impedance Z_{LRA}, DC resistance Re, and an a-priori choice for factor Re_cancel.

Negative impedance filter transfer function may be a third-order digital filter with z-transform represented as:

$${Z}_{NIF} ( z ) = \frac{b0\_nif + b1\_nif * {z}^{- 1} + b2\_nif * {z}^{- 2} + b3\_nif * {z}^{- 3}}{1 + a1\_nif * {z}^{- 1} + a2\_nif * {z}^{- 2} + a3\_nif * {z}^{- 3}} \qquad ( 11 )$$

The coefficients b0_nif, b1_nif, b2_nif, b3_nif, α1_nif, α2_nif, and α3_nif of negative impedance filter 626 may embody the information about transducer impedance Z_{LRA}, DC resistance Re, and factor Re_cancel.

Example methods and systems for online real-time estimation of parameters of haptic transducer impedance Z_{LRA} are described in U.S. Provisional Patent Application Ser. No. 62/826,388, filed Mar. 29, 2019, and in any application claiming priority thereto, all of which are incorporated by reference in their entireties, and may be referred to herein as the “Estimating Patent Application” and is incorporated by reference in its entirety.

In the “Estimating Patent Application,” a method is described that separates the estimation problem into an estimation of coil impedance Z_{coil}=Re+Le*s on the one hand and estimation of mechanical impedance Z_{mech} on the other. In particular, the electrical equivalent of mechanical impedance Z_{mech} may be estimated using least-squares estimation as a second-order system which is then placed in series with coil impedance Z_{coil} to determine a third-order haptic transducer impedance Z_{LRA}. In the “Estimating Patent Application,” a second-order mechanical impedance Z_{mech} may be estimated from three least-squares parameter estimates: g, α1, and α2. A full haptic transducer impedance Z_{LRA} may then be estimated from these three parameters plus separately estimated DC coil resistance Re and coil inductance Le.

$${Z}_{LRA} = \frac{{V}_{LRA} ( s )}{{I}_{LRA} ( s )}$$

is a transfer function that may describe a filter that takes current as input and produces a voltage as output. However, it may desirable to find parameters b0_nif, b1_nif, b2_nif, b3_nif, α1_nif, α2_nif, and α3_nif for negative impedance filter 626 that describes a voltage divider that takes Vₑ(z)=V_{LRA} (z) as input and produces voltage Vₘ(z) as output. By using equation (9) from above and knowledge of separately estimated DC coil resistance Re (e.g., it may be assumed that coil inductance Le is fixed and estimated a-priori by laboratory measurements or other means), expressions for negative impedance filter 626 may be provided. Substituting the expressions for haptic transducer impedance Z_{LRA} involving g, α1, α2 and Re from the “Estimating Patent Application” into equation (9) above, and applying the Bilinear Transform to convert from continuous time to discrete (digital) time, expressions for parameters b0_nif, b1_nif, b2_nif, b3_nif, α1_nif, α2_nif, and α3_nif may be derived for negative impedance filter 626. An inductance Le_nrm and an impedance Zfb may be defined by:

$$Le\_nrm = 2 * Le * fs ;$$

$$Zfb = Re\_cancel * Re ;$$

Unnormalized coefficients for the negative impedance filter 626 may be defined as:

$$b0\_nif = - Le\_nrm - Re - g ;$$

$$b1\_nif = Le\_nrm - Re - g - Le\_nrm * a 1 - Re * a 1 ;$$

$$b2\_nif = g + Le\_nrm * a 1 - Le\_nrm * a 2 - Re * a 1 - Re * a 2 ;$$

$$b3\_nif = g + Le\_nrm * a 2 - Re * a 2 ;$$

$$a0\_nif = Zfb - Le\_nrm - Re - g ;$$

$$a1\_nif = Zfb + Le\_nrm - Re - g + Zfb * a 1 - Le\_nrm * a 1 - Re * a 1 ;$$

$$a2\_nif = g + Zfb * a 1 + Zfb * a 2 + Le\_nrm * a 1 - Le\_nrm * a 2 - Re * a 1 - Re * a 2 ;$$

$$and$$

$$a3\_nif = g + Zfb * a 2 + Le\_nrm * a 2 - Re * a 2.$$

All of these expressions may further be normalized by dividing the above coefficients by α0_nif to arrive at final parameter coefficients b0_nif, b1_nif, b2_nif, b3_nif, α1_nif, α2_nif, and α3_nif of negative impedance filter 626.

The transfer function of negative impedance filter 626 may be a third-order digital filter with a z-transform represented as:

$${Z}_{NIF} ( z ) = \frac{b0\_nif + b1\_nif * {z}^{- 1} + b2\_nif * {z}^{- 2} + b3\_nif * {z}^{- 3}}{1 + a1\_nif * {z}^{- 1} + a2\_nif * {z}^{- 2} + a3\_nif * {z}^{- 3}} \qquad ( 12 )$$

wherein coefficients b0_nif, b1_nif, b2_nif, b3_nif, α1_nif, α2_nif, and α3_nif of negative impedance filter 626 embody information about transducer impedance Z_{LRA}, DC resistance Re, and factor Re_cancel.

In some embodiments, knowledge of the electrical and electrical equivalent transducer parameters Re, Le, R_{RES}, C_{MES}, L_{CES} may be obtained offline. This knowledge may result from laboratory measures of a transducer device and/or from data published by a transducer manufacturer.

The expression for the transfer function of negative impedance filter 626 function given in equation (9) is in the form of an s-domain Laplace transform. Such expression may be converted to a digital z-transform using any number of standard techniques such as the Bilinear Transform, the Impulse Invariant Transform, and others.

By substituting equation (2) for transducer impedance Z_{LRA} and equation (10) for negative resistance Re_neg in equation (9), the transfer function of negative impedance filter 626 may be expressed as

$${Z}_{NIF} ( s ) = \frac{{Z}_{coil} ( s ) + {Z}_{mech} ( s )}{( {Z}_{coil} ( s ) + {Z}_{mech} ( s ) - Re * Re\_cancel )} \qquad ( 13 )$$

Further substituting equation (3) for Z_{coil}(s) and equation (4) for Z_{mech} (s) gives:

$${Z}_{NIF} ( s ) = \frac{Re + s * Le + ( \frac{1}{( \frac{1}{{R}_{RES}} + \frac{1}{{L}_{CES} * s} + {c}_{MES} * s )} )}{( Re + s * Le + ( \frac{1}{( \frac{1}{{R}_{RES}} + \frac{1}{{L}_{CES} * s} + {c}_{MES} * s )} ) - Re * Re\_cancel )} \qquad ( 14 )$$

Equation (13) may thus provide an expression for the Laplace transform of the transfer function Z_{NIF}(S) of negative impedance filter 626 in terms of the electrical and electrical equivalent parameters Re, Le, R_{RES}, C_{MES}, L_{CES} as well as factor Re_cancel. To transform equation (14) to a digital filter z-transform using the Bilinear Transform, the Laplace variable s may be substituted according to:

$$s = 2 * fs * \frac{( z - 1 )}{( z + 1 )} \qquad ( 15 )$$

If equation (15) is substituted into equation (14) and then simplified, an equation for the digital z-transform Z_{NIF}(Z) is obtained in the form of equation (12), where the coefficients b0_nif, b1_nif, b2_nif, b3_nif, α1_nif, α2_nif, and α3_nif are expressed in terms of Re, Le, R_{RES}, C_{MES}, L_{CES} as well as factor Re_cancel, according to:

$$b0\_nif = ( Re * Rres + 2 * Lces * Re * fs + 2 * Lces * Rres * fs + 2 * Le * Rres * fs + 4 * Lces * Le * {fs}^{2} + 8 * Cmes * Lces * Le * Rres * {fs}^{3} + 4 * Cmes * Lces * Re * Rres * {fs}^{2} ) / ( Re * Rres - Re * Re\_cancel * Rres + 2 * Lces * Re * fs + 2 * Lces * Rres * fs + 2 * Le * Rres * fs + 4 * Lces * Le * {fs}^{2} - 2 * Lces * Re * Re\_cancel * fs + 8 * Cmes * Lces * Le * Rres * {fs}^{3} + 4 * Cmes * Lces * Re * Rres * {fs}^{2} - 4 * Cmes * Lces * Re * Re\_cancel * Rres * {fs}^{2} ) ;$$

$$b1\_nif = ( 3 * Re * Rres + 2 * Lces * Re * fs + 2 * Lces * Rres * fs + 2 * Le * Rres * fs - 4 * Lces * Le * {fs}^{2} - 24 * Cmes * Lces * Le * Rres * {fs}^{3} - 4 * Cmes * Lces * Re * Rres * {fs}^{2} ) / ( Re * Rres - Re * Re\_cancel * Rres + 2 * Lces * Re * fs + 2 * Lces * Rres * fs + 2 * Le * Rres * fs + 4 * Lces * Le * {fs}^{2} - 2 * Lces * Re * Re\_cancel * fs + 8 * Cmes * Lces * Le * Rres * {fs}^{3} + 4 * Cmes * Lces * Re * Rres * {fs}^{2} - 4 * Cmes * Lces * Re * Re\_cancel * Rres * {fs}^{2} ) ;$$

$$b2\_nif = - ( 2 * Lces * Re * fs - 3 * Re * Rres + 2 * Lces * Rres * fs + 2 * Le * Rres * fs + 4 * Lces * Le * {fs}^{2} - 24 * Cmes * Lces * Le * Rres * {fs}^{3} + 4 * Cmes * Lces * Re * Rres * {fs}^{3} ) / ( Re * Rres - Re * Re\_cancel * Rres + 2 * Lces * Re * fs + 2 * Lces * Rres * fs + 2 * Le * Rres * fs + 4 * Lces * Le * {fs}^{2} - 2 * Lces * Re * Re\_cancel * fs + 8 * Cmes * Lces * Le * Rres * {fs}^{3} + 4 * Cmes * Lces * Re * Rres * {fs}^{2} - 4 * Cmes * Lces * Re * Re\_cancel * Rres * {fs}^{2} ) ;$$

$$b3\_nif = - ( 2 * Lces * Re * fs - Re * Rres + 2 * Lces * Rres * fs + 2 * Le * Rres * fs - 4 * Lces * Le * {fs}^{2} + 8 * Cmes * Lces * Le * Rres * {fs}^{3} - 4 * Cmes * Lces * Re * Rres * {fs}^{2} ) / ( Re * Rres - Re * Re\_cancel * Rres + 2 * Lces * Re * fs + 2 * Lces * Rres * fs + 2 * Le * Rres * fs + 4 * Lces * Le * {fs}^{2} - 2 * Lces * Re * Re\_cancel * fs + 8 * Cmes * Lces * Le * Rres * {fs}^{3} + 4 * Cmes * Lces * Re * Rres * {fs}^{2} - 4 * Cmes * Lces * Re * Re\_cancel * Rres * {fs}^{2} ) ;$$

$$a1\_nif = ( 3 * Re * Rres - 3 * Re * Re\_cancel * Rres + 2 * Lces * Re * fs + 2 * Lces * Rres * fs + 2 * Le * Rres * fs - 4 * Lces * Le * {fs}^{2} - 2 * Lces * Re * Re\_cancel * fs - 24 * Cmes * Lces * Le * Rres * {fs}^{3} - 4 * Cmes * Lces * Re * Rres * {fs}^{2} + 4 * Cmes * Lces * Re * Re\_cancel * Rres * {fs}^{2} ) / ( Re * Rres - Re * Re\_cancel * Rres + 2 * Lces * Re * fs + 2 * Lces * Rres * fs + 2 * Le * Rres * fs + 4 * Lces * Le * {fs}^{2} - 2 * Lces * Re * Re\_cancel * fs + 8 * Cmes * Lces * Le * Rres * {fs}^{3} + 4 * Cmes * Lces * Re * Rres * {fs}^{2} - 4 * Cmes * Lces * Re * Re\_cancel * Rres * {fs}^{2} ) ;$$

$$a2\_nif = - ( 3 * Re * Re\_cancel * Rres - 3 * Re * Rres + 2 * Lces * Re * fs + 2 * Lces * Rres * fs + 2 * Le * Rres * fs + 4 * Lces * Le * {fs}^{2} - 2 * Lces * Re * Re\_cancel * fs - 24 * Cmes * Lces * Le * Rres * {fs}^{3} + 4 * Cmes * Lces * Re * Rres * {fs}^{2} - 4 * Cmes * Lces * Re * Re\_cancel * Rres * {fs}^{2} ) / ( Re * Rres - Re * Re\_cancel * Rres + 2 * Lces * Re * fs + 2 * Lces * Rres * fs + 2 * Le * Rres * fs + 4 * Lces * Le * {fs}^{2} - 2 * Lces * Re * Re\_cancel * fs + 8 * Cmes * Lces * Le * Rres * {fs}^{3} + 4 * Cmes * Lces * Re * Rres * {fs}^{2} - 4 * Cmes * Lces * Re * Re\_cancel * Rres * {fs}^{2} )$$

$$a3\_nif = - ( Re * Re\_cancel * Rres - Re * Rres + 2 * Lces * Re * fs + 2 * Lces * Rres * fs + 2 * Le * Rres * fs - 4 * Lces * Le * {fs}^{2} - 2 * Lces * Re * Re\_cancel * fs + 8 * Cmes * Lces * Le * Rres * {fs}^{3} - 4 * Cmes * Lces * Re * Rres * {fs}^{2} + 4 * Cmes * Lces * Re * Re\_cancel * Rres * {fs}^{2} ) / ( Re * Rres - Re * Re\_cancel * Rres + 2 * Lces * Re * fs + 2 * Lces * Rres * fs + 2 * Le * Rres * fs + 4 * Lces * Le * {fs}^{2} - 2 * Lces * Re * Re\_cancel * fs + 8 * Cmes * Lces * Le * Rres * {fs}^{3} + 4 * Cmes * Lces * Re * Rres * {fs}^{2} - 4 * Cmes * Lces * Re * Re\_cancel * Rres * {fs}^{2} )$$

In embodiments in which parameters Re, Le, R_{RES}, C_{MES}, L_{CES} as well as factor Re_cancel are obtained offline, the expressions above may be used to compute the coefficients for the negative impedance filter 626.

Although the foregoing discusses application to a linear electromagnetic load, it is understood that systems and methods similar or identical to those disclosed may be applied to other linear or non-linear systems.

Further, although the foregoing contemplates use of a negative resistance filter to implement a model of an LRA, in some embodiments a mathematical equivalent to an LRA may be used in lieu of a model.

Accordingly, using the systems and methods described above, a system (e.g., system 600) may include a signal generator (e.g., pulse generator 622) configured to generate a raw waveform signal (e.g., raw waveform signal x′(t)) and a modeling subsystem (e.g., negative impedance filter 626) configured to implement a discrete time model (e.g., model shown in FIG. 7) of an electromagnetic load (e.g., haptic transducer 601) that emulates a virtual electromagnetic load and further configured to modify the raw waveform signal to generate a waveform signal (e.g., waveform signal x(t)) for driving the electromagnetic load by modifying the virtual electromagnetic load to have a desired characteristic (e.g., applying negative resistance 706), applying the discrete time model to the raw waveform signal to generate the waveform signal for driving the electromagnetic load, and applying the waveform signal to the electromagnetic load.

Further, in some embodiments, the generated waveform signal for driving the electromagnetic load may be stored to a memory or other non-transitory computer-readable medium for later retrieval and playback to an electromagnetic load, for use in of the same electromagnetic load in the same device or another electromagnetic load in a similar device.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A non-transitory computer readable medium having stored thereon data encoding a waveform signal for playback, wherein the waveform signal is generated by:
implementing a discrete time model of a physical electromagnetic load that emulates a virtual electromagnetic load; and
modifying a raw waveform signal to generate a waveform signal for driving the physical electromagnetic load by:
modifying the virtual electromagnetic load to have a desired characteristic; and
applying the discrete time model to the raw waveform signal to generate the waveform signal for driving the physical electromagnetic load.

2. The non-transitory computer readable medium of claim 1, wherein the electromagnetic load is a haptic transducer.

3. The non-transitory computer readable medium of claim 1, wherein the discrete time model is based on one or more parameters of the electromagnetic load determined based on laboratory simulation.

4. The non-transitory computer readable medium of claim 1, wherein the discrete time model is based on one or more parameters of the electromagnetic load determined based on real-time estimation of the one or more parameters during operation of the system.

5. The non-transitory computer readable medium of claim 4, wherein the real-time estimation is performed based on broadband content of at least a beginning of a transient of the waveform signal.

6. The non-transitory computer readable medium of claim 4, wherein the real-time estimation is performed based on broadband content of at least an end of a transient of the waveform signal.

7. The non-transitory computer readable medium of claim 4, wherein the modeling subsystem is configured to periodically update the real-time estimation in order to achieve the desired characteristic.

8. The non-transitory computer readable medium of claim 1, wherein the desired characteristic is a desired impedance of a virtual transducer.

9. A method comprising:
implementing a discrete time model of an electromagnetic load that emulates a virtual electromagnetic load; and
modifying a raw waveform signal to generate a waveform signal for driving the electromagnetic load by:
modifying the virtual electromagnetic load to have a desired characteristic;
applying the discrete time model to the raw waveform signal to generate the waveform signal for driving the electromagnetic load; and
storing the waveform signal to a non-transitory computer-readable medium.

10. The method of claim 9, wherein the electromagnetic load is a haptic transducer.

11. The method of claim 9, wherein the discrete time model is based on one or more parameters of the electromagnetic load determined based on laboratory simulation.

12. The method of claim 9, wherein the discrete time model is based on one or more parameters of the electromagnetic load determined based on real-time estimation of the one or more parameters during operation of the system.

13. The method of claim 12, wherein the real-time estimation is performed based on broadband content of at least a beginning of a transient of the waveform signal.

14. The method of claim 12, wherein the real-time estimation is performed based on broadband content of at least a beginning of an end of a transient of the waveform signal.

15. The method of claim 12, further comprising periodically updating the real-time estimation in order to achieve the desired characteristic.

16. The method of claim 9, wherein the desired characteristic is a desired impedance of a virtual transducer.

17. A system comprising:
a signal generator configured to generate a raw waveform signal; and
a modeling subsystem configured to implement a discrete time model of an electromagnetic load that emulates a virtual electromagnetic load and further configured to modify the raw waveform signal to generate a waveform signal for driving the electromagnetic load by:
modifying the virtual electromagnetic load to have a desired characteristic;
applying the discrete time model to the raw waveform signal to generate the waveform signal for driving the electromagnetic load; and
storing the waveform signal to a non-transitory computer-readable medium.

18. The system of claim 17, wherein the electromagnetic load is a haptic transducer.

19. The system of claim 17, wherein the discrete time model is based on one or more parameters of the electromagnetic load determined based on laboratory simulation.

20. The system of claim 17, wherein the discrete time model is based on one or more parameters of the electromagnetic load determined based on real-time estimation of the one or more parameters during operation of the system.

21. The system of claim 20, wherein the real-time estimation is performed based on broadband content of at least a beginning of a transient of the waveform signal.

22. The system of claim 20, wherein the real-time estimation is performed based on broadband content of at least an end of a transient of the waveform signal.

23. The system of claim 20, wherein the modeling subsystem is configured to periodically update the real-time estimation in order to achieve the desired characteristic.

24. The system of claim 17, wherein the desired characteristic is a desired impedance of a virtual transducer.
